(19) United States
(12) Patent Application Publication
(10) Pub. No.: US 2024/0023415 A1
(43) Pub. Date: Jan. 18, 2024

(54) DISPLAY DEVICE INCLUDING LENTICULAR LENSES

(71) Applicant: SAMSUNG DISPLAY CO., LTD., Yongin-si (KR)

(72) Inventors: Byeong Hee WON, Yongin-si (KR); Jeong Woo PARK, Yongin-si (KR)

(21) Appl. No.: 18/301,580

(22) Filed: Apr. 17, 2023

(30) Foreign Application Priority Data
Jul. 12, 2022 (KR) 10-2022-0085902

(51) Int. Cl. H10K 59/80; H10K 59/35; G02B 30/27

(52) U.S. Cl. CPC H10K 59/879; H10K 59/353; G02B 30/27

(57) ABSTRACT

A display device includes a plurality of sub-pixels arranged in a first direction and a second direction perpendicular to the first direction; and a plurality of lenticular lenses arranged such that an edge of a long side of each of the lenticular lenses has a first angle with respect to the second direction. A first sub-pixel of the sub-pixels includes a first edge extending in the first direction; a second edge extending in the second direction and connected to the first edge; a third edge parallel to the first edge; a fourth edge parallel to the second edge; and a fifth edge connecting the second edge with the third edge.

### CROSS-REFERENCE TO RELATED APPLICATION

The present application claims priority under 35 U.S.C. § 119 to Korean patent application number 10-2022-0085902, filed in the Korean Intellectual Patent Office on Jul. 12, 2022, the entire disclosure of which is incorporated by reference herein in its entirety.

### TECHNICAL FIELD

The present disclosure relates to a display device and, more specifically, to a display device including lenticular lenses.

### DISCUSSION OF THE RELATED ART

With the development of information technology, the importance of a display device, has been emphasized. Owing to the importance of display devices, the use of various kinds of display devices, such as a liquid crystal display device and an organic light-emitting display device, has increased.

A stereoscopic image display device is a display device which provides a perception of seeing an image in three dimensions. For example, the stereoscopic image display device may provide different images to the left and right eyes of the viewer so that the viewer can view the stereoscopic image by binocular parallax between the left and right eyes.

One approach for providing three-dimensional image display is to use special three-dimensional (“3D”) glasses in which an image from a display device is filtered at each eye so that the viewer's left eye receives the display's left-eye image and the viewer's right eye receives the display's right eye image. Other approaches for providing three-dimensional image display do not require the use of special glasses. For example, a display device may utilize lenticular lenses to direct eye-specific images to each of the viewer's eyes. Such methods may separate left and right eye images using a cylindrical lens array. Additionally, a barrier method may be utilized in which left and right eye images are separated using a barrier.

### SUMMARY

A display device includes a plurality of sub-pixels arranged in a first direction and a second direction perpendicular to the first direction; and a plurality of lenticular lenses arranged such that an edge of a long side of each of the lenticular lenses has a first angle with respect to the second direction. A first sub-pixel of the sub-pixels includes a first edge extending in the first direction; a second edge extending in the second direction and connected to the first edge; a third edge parallel to the first edge; a fourth edge parallel to the second edge; and a fifth edge connecting the second edge with the third edge.

The fifth edge may extend parallel to the edge of the long side of each of the lenticular lenses.

The first sub-pixel may further include a sixth edge connecting the first edge with the fourth edge.

The sixth edge may extend parallel to the edge of the long side of each of the lenticular lenses.

The first sub-pixel may correspond to a first color. The sub-pixels may further include: a second sub-pixel disposed on a side of the first sub-pixel in the first direction and corresponding to a second color; and a third sub-pixel disposed on a side of the second sub-pixel in the first direction and corresponding to a third color. The first color, the second color, and the third color may differ from each other.

The sub-pixels may further include a fourth sub-pixel disposed on a side of the first sub-pixel in the second direction and corresponding to a first color.

Each of the second sub-pixel and the third sub-pixel may include an edge aligned with the first edge of the first sub-pixel in the first direction.

Each of the second sub-pixel and the third sub-pixel may further include an edge aligned with the third edge of the first sub-pixel in the first direction.

The fourth sub-pixel may include an edge aligned with the second edge of the first sub-pixel in the second direction.

The fourth sub-pixel may further include an edge aligned with the fourth edge of the first sub-pixel in the second direction.

A display device includes a plurality of sub-pixels arranged in a first direction and a second direction perpendicular to the first direction; and a plurality of lenticular lenses arranged such that an edge of a long side of each of the lenticular lenses has a first angle with respect to the second direction. A first sub-pixel of the sub-pixels includes a first edge extending in the first direction; a second edge extending in the second direction and connected to the first edge; a third edge parallel to the first edge; a fourth edge parallel to the second edge; a fifth edge including one end connected to the second edge; and a sixth edge connecting the fifth edge with the third edge.

The fifth edge may have a second angle with respect to the edge of the long side of each of the lenticular lenses. The second angle may be less than the first angle.

The sixth edge may have a third angle with respect to the edge of the long side of each of the lenticular lenses. The third angle may be less than the first angle.

The second angle may be identical to the third angle.

The first sub-pixel may further include: a seventh edge including one end connected to the first edge; and an eighth edge connecting the fourth edge with the seventh edge.

The seventh edge may be parallel to the sixth edge. The eighth edge may be parallel to the fifth edge.

The first sub-pixel may correspond to a first color. The sub-pixels may further include: a second sub-pixel disposed on a side of the first sub-pixel in the first direction and corresponding to a second color; and a third sub-pixel disposed on a side of the second sub-pixel in the first direction and corresponding to a third color. The first color, the second color, and the third color may differ from each other.

The sub-pixels may further include a fourth sub-pixel disposed on a side of the first sub-pixel in the second direction and corresponding to a first color.

Each of the second sub-pixel and the third sub-pixel may include an edge aligned with the first edge of the first sub-pixel in the first direction. Each of the second sub-pixel and the third sub-pixel may further include an edge aligned with the third edge of the first sub-pixel in the first direction.

The fourth sub-pixel may include an edge aligned with the second edge of the first sub-pixel in the second direction. The fourth sub-pixel may further include an edge aligned with the fourth edge of the first sub-pixel in the second direction.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a diagram illustrating a lens array-type stereoscopic image display device.

FIG. 2 is a diagram illustrating a relationship between a lens array and a pixel component.

FIG. 3 is a diagram illustrating sub-pixels in accordance with an embodiment of the present disclosure.

FIG. 4 is a diagram illustrating a crosstalk reduction effect of the sub-pixels of FIG. 3.

FIG. 5 is a diagram illustrating sub-pixels in accordance with an embodiment of the present disclosure.

### DETAILED DESCRIPTION

Hereinafter, embodiments of the present invention will be described in detail with reference to the attached drawings, such that those skilled in the art can practice the present invention. The present disclosure may be implemented in various forms, and is not necessarily limited to the embodiments to be described herein below.

In the drawings, portions which are not related to the present disclosure may be omitted in order to explain the present disclosure more clearly. In the drawings, similar reference numerals may be used throughout the different drawings to designate similar components.

While each drawing may represent one or more particular embodiments of the present, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

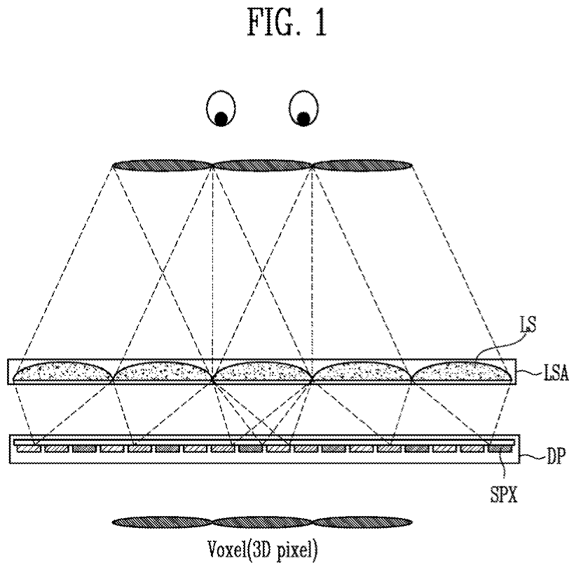

FIG. 1 is a diagram illustrating a lens array-type stereoscopic image display device.

Referring to FIG. 1, the stereoscopic image display device may include a display panel DP and a lens array LSA.

The display panel DP may include sub-pixels SPX which emit light to display an image. In an embodiment, each of the sub-pixels SPX may output one of red light, green light, and blue light. However, the foregoing is merely illustrative, and the color of the light emitted from the sub-pixel SPX is not necessarily limited thereto, and various colors of light may be outputted to implement a full-color image. The display panel DP may include an organic light emitting display panel, a liquid crystal display panel, a quantum dot display panel, or the like.

The lens array LSA may be disposed on the display panel DP, and may include lenses LS that refract light that is incident thereon from the sub-pixels SPX. For example, the lens array LSA may be implemented as a lenticular lens array, a micro lens array, or the like.

A light field display is a 3D display device which forms a light field expressed by vector distribution (e.g., intensity, direction) of light on a space using a flat panel display and an optical element (e.g. a lens array LSA) to embody a stereoscopic image. The light field display pertains to a display technology which is expected to be used in various applications by fusion with an augmented reality (“AR”) technology, and the like because the light field display allows a user to recognize the depth of a target object and see a side surface of the target object and thus can embody a more natural stereoscopic image.

The light filed may be implemented in various ways. For example, the light field may be formed by making a multi-directional light field using multiple projectors, by controlling the direction of light using a diffraction grating, by controlling the direction and intensity (e.g., luminance) of light according to the combination of each pixel using two or more panels, by controlling the direction of light using a pinhole or a barrier, or by controlling the refraction direction of light through the lens array, or the like.

In an embodiment, as illustrated in FIG. 1, the lens array-type stereoscopic image display device may display a stereoscopic image (e.g., a 3D image) by forming the light field.

A series of sub-pixels SPX may be allocated to each lens LS, and light emitted from each sub-pixel SPX may be refracted by the lens LS to travel only in a specific direction, thus forming a light field expressed by the intensity and direction of light. When a viewer looks at the stereoscopic image display device in the light field formed by the foregoing method, the viewer can experience a three-dimensional effect of a corresponding image.

Image information according to a viewpoint of the viewer in the light field may be defined and processed on a voxel basis. The voxel may be understood as graphic information defining a certain point (or pixel) in a 3D space.

The resolution of a two-dimensional (2D) image may be determined as the number of pixels per unit area (e.g., density). For example, in the case where the number of pixels per unit area increases, the resolution may increase. For example, a display panel DP having a relatively high pixel density may be needed to provide a high resolution image. Likewise, if the number of voxels at the same viewpoint is increased by the lens array LSA, the resolution of a stereoscopic image may be increased.

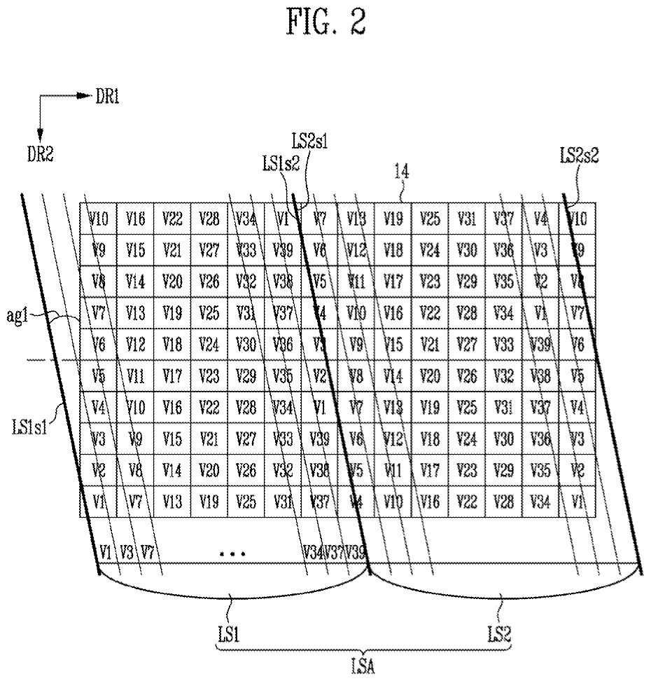

FIG. 2 is a diagram illustrating a relationship between the lens array LSA and a pixel component 14.

The pixel component 14 may include sub-pixels arranged in a first direction DR1 and a second direction DR2 perpendicular to the first direction DR1.

The lens array LSA may include lenses LS1, LS2, . . . . Each of the lenses LS1, LS2, . . . may be a lenticular lens which is inclined such that an edge of a long side thereof has a first angle ag1 with respect to the second direction DR2. For example, the first lens LS1 may include a first long side LS1s1 and a second long side LS1s2 which are parallel to each other. Furthermore, the second lens LS2 may include a first long side LS2s1 and a second long side LS2s2 which are parallel to each other. The lenses LS1, LS2, . . . may be arranged in the first direction DR1.

A lower surface (a surface facing the sub-pixels) of each of the lenses LS1, LS2, . . . may be partitioned into a plurality of viewpoint areas V1 to V39. The viewpoint areas V1 to V39 may be imaginary areas rather than being physically partitioned from each other, and may be defined in various ways depending on the resolution of the pixel component 14, specifications of the lenses LS1, LS2, . . . , the number of viewpoints to be provided to the user, or the like. As each of the lenses LS1, LS2, . . . distributes images corresponding to the respective viewpoint areas V1 to V39 to different directions (different viewpoints), the user can see a multi-view image which varies depending on the location.

The sub-pixels may overlap one or more of the viewpoint areas V1 to V39. In FIG. 2, there are designated principal viewpoint areas V1 to V39 corresponding to the sub-pixels. The sub-pixels that correspond to the same viewpoint area may display an image corresponding to the same viewpoint. For example, in FIG. 2, thirty-nine viewpoint areas V1 to V39 are present, so that the pixel component 14 may display thirty-nine images.

In the display device, the sub-pixels that overlap the viewpoint areas V1 to V20 may display a right-eye image, and the sub-pixels that overlap the viewpoint areas V21 to V39 may display a left-eye image, whereby the display device can display a stereoscopic image. In this case, the user is needed to be located such that the left-eye image is visible to the left eye, and the right-eye image is visible to the right eye.

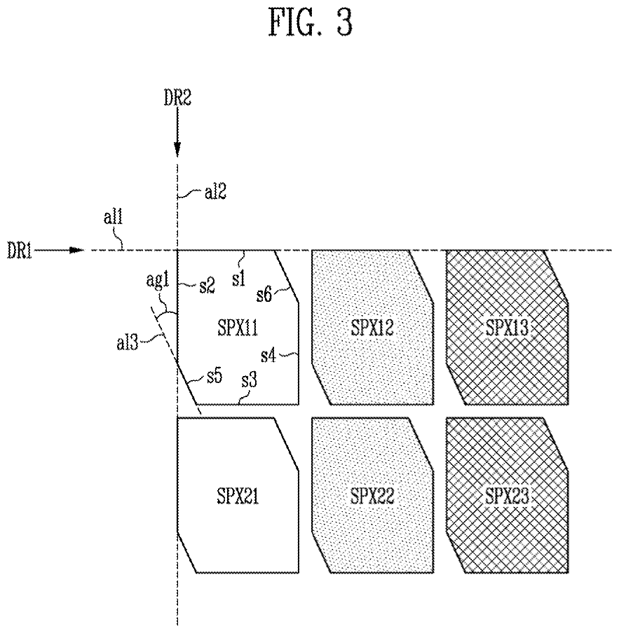

FIG. 3 is a diagram illustrating sub-pixels in accordance with an embodiment of the present disclosure.

FIG. 3 illustrates sub-pixels SPX11, SPX12, SPX13, SPX21, SPX22, and SPX23 which are parts of the pixel component 14. Although in the present embodiment there is illustrated the case where the sub-pixels SPX11 to SPX23 are arranged in an RGB stripe structure, the sub-pixels SPX11 to SPX23 may be arranged in various conventional pixel arrangement schemes (e.g., a diamond PENTILE′, an S-stripe, a real RGB, and a normal PENTILE™).

In FIGS. 1 to 5, locations and shapes of the sub-pixels SPX11 to SPX23 refer to locations and shapes of the emission surfaces of the light emitting elements of the sub-pixels SPX11 to SPX23. Therefore, the location or shape of the pixel circuit of each of the sub-pixels SPX11 to SPX23 is not necessarily limited to that of the present embodiment.

The first sub-pixel SPX11 and the fourth sub-pixel SPX21 may be sub-pixels of a first color. The second sub-pixel SPX12 and the fifth sub-pixel SPX22 may be sub-pixels of a second color. The third sub-pixel SPX13 and the sixth sub-pixel SPX23 may be sub-pixels of a third color. The first color, the second color, and the third color may be different from each other. Here, the color of each sub-pixel may indicate a color expressed from the sub-pixel when the sub-pixel emits light.

The second sub-pixel SPX12 may be located on a side of the first sub-pixel SPX11 in the first direction DR1. The third sub-pixel SPX13 may be located on a side of the second sub-pixel SPX12 in the first direction DR1. The fourth sub-pixel SPX21 may be located on a side of the first sub-pixel SPX11 in the first direction DR2. The fifth sub-pixel SPX22 may be located on a side of the fourth sub-pixel SPX21 in the first direction DR1. The sixth sub-pixel SPX23 may be located on a side of the fifth sub-pixel SPX22 in the first direction DR1.

Scan lines of the display device may extend in the first direction DR1. Data lines of the display device may extend in the second direction DR2. Here, the pixel circuits of the first, second, and third sub-pixels SPX11, SPX12, and SPX13 may be connected to the same scan lines. Furthermore, the pixel circuits of the fourth, fifth, and sixth sub-pixels SPX21, SPX22, and SPX23 may be connected to the same scan lines. Here, the pixel circuits of the first sub-pixel SPX11 and the fourth sub-pixel SPX21 may be connected to the same data line. Furthermore, the pixel circuits of the second sub-pixel SPX12 and the fifth sub-pixel SPX22 may be connected to the same data line. Furthermore, the pixel circuits of the third sub-pixel SPX13 and the sixth sub-pixel SPX23 may be connected to the same data line.

In an embodiment, the sub-pixels SPX11, SPX12, SPX13, SPX21, SPX22, SPX23, . . . of the pixel component 14 may have substantially the same shape. In the following description, the shape of the first sub-pixel SPX11 is the same as that of each of the remaining sub-pixels SPX12, SPX13, SPX21, SPX22, SPX23, . . . ; therefore, it may be assumed that the remaining sub-pixels SPX12, SPX13, SPX21, SPX22, SPX23, . . . have a similar structure.

The first sub-pixel SPX11 may include first to sixth edges s1, s2, s3, s4, s5, and s6. The first edge s1 may extend in the first direction DR1. The second edge s2 may extend in the second direction DR2 and be connected to the first edge s1. The third edge s3 may be parallel to the first edge s1. The fourth edge s4 may be parallel to the second edge s2. The fourth edge s4 may be connected to the third edge s3. The fifth edge s5 may connect the second edge s2 with the third edge s3. The sixth edge s6 may connect the first edge s1 with the fourth edge s4. The first to sixth edges s1 to s6 each may have a linear shape.

The second sub-pixels SPX12 and the third sub-pixel SPX13 may respectively include edges aligned with the first edge s1 of the first sub-pixel SPX11 in the first direction DR1. It may be assumed that a first alignment line a11, which is an imaginary line, overlaps the first edge s1 and extends in the first direction DR1. Here, the second sub-pixel SPX12 and the third sub-pixel SPX13 may respectively include edges located on the first alignment line a11. Likewise, the second sub-pixels SPX12 and the third sub-pixel SPX13 may respectively further include edges aligned with the third edge s3 of the first sub-pixel SPX11 in the first direction DR1.

The fourth sub-pixel SPX21 may include an edge aligned with the second edge s2 of the first sub-pixel SPX11 in the second direction DR2. It may be assumed that a second alignment line a12, which is an imaginary line, overlaps the second edge s2 and extends in the second direction DR2. Here, the fourth sub-pixel SPX21 may include an edge located on the second alignment line a12. Likewise, the fourth sub-pixel SPX21 may include an edge aligned with the fourth edge s4 of the first sub-pixel SPX11 in the second direction DR2.

Each of the fifth edge s5 and the sixth edge s6 may extend parallel to edges of the long sides of the lens LS1, LS2, . . . . It may be assumed that a third alignment line a13, which is an imaginary line, overlaps the fifth edge s5 and linearly extends. Here, the second edge s2 may have a first angle ag1 with respect to the third alignment line a13. The first angle ag1 of FIG. 3 and the first angle ag1 of FIG. 2 may be equal to each other.

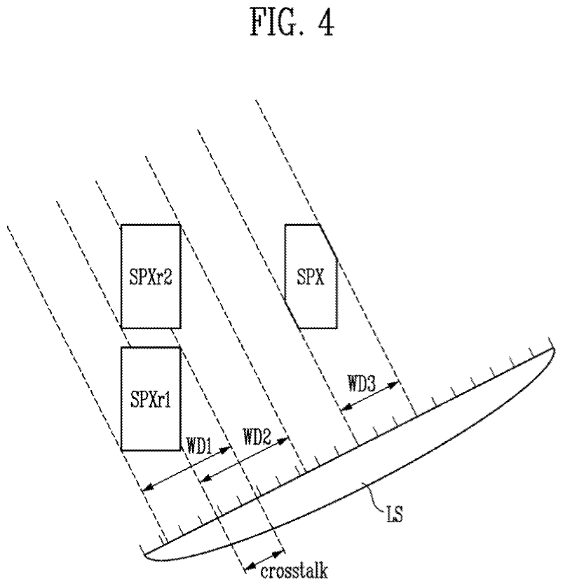

FIG. 4 is a diagram illustrating a crosstalk reduction effect of the sub-pixels of FIG. 3.

Referring to FIG. 4, there are illustrated conventional rectangular sub-pixels SPXr1 and SPXr2 and a hexagonal sub-pixel SPX according to an embodiment of the present disclosure.

Each of widths WD1 and WD2 of the sub-pixels SPXr1 and SPXr2 that overlap a plurality of viewpoint areas of the lens LS may be greater than a width WD3 of the sub-pixel SPX that overlaps a plurality of viewpoint areas of the lens LS. For example, while each of the widths WD1 and WD2 of the sub-pixels SPXr1 and SPXr2 are four viewpoint areas of the lens LS, the width WD3 of the sub-pixel SPX may overlap three viewpoint areas of the lens LS. Because a reduction in width means that an overlap area between sub-pixels is reduced, the crosstalk may be minimized in accordance with an embodiment of the present disclosure.

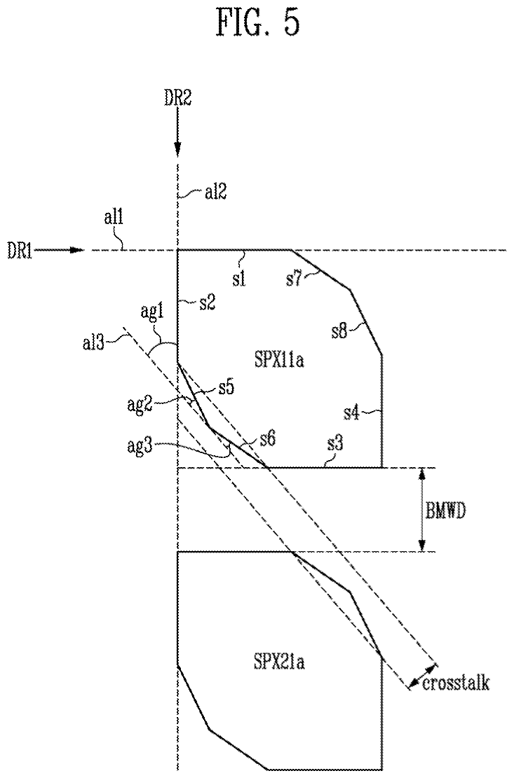

FIG. 5 is a diagram illustrating sub-pixels in accordance with an embodiment of the present disclosure.

Referring to FIG. 5, there are illustrated a first sub-pixel SPX11a and a fourth sub-pixel SPX21a. First to fourth edges s1, s2, s3, and s4 of the first sub-pixel SPX11a of FIG. 5 may be respectively the same as the first to fourth edges s1, s2, s3, and s4 of the first sub-pixel SPX11 of FIG. 3. Imaginary alignment lines a11, a12, and a13 of FIG. 5 may respectively the same as the imaginary alignment lines a11, a12, and a13 of FIG. 3. Therefore, although FIG. 5 does not illustrate a second sub-pixel, a third sub-pixel, a fifth sub-pixel, and a sixth sub-pixel, the same description as that of the second to sixth sub-pixels SPX12 to SPX23 of FIG. 3 can be applied to that of FIG. 5.

The following descriptions will be focused on differences between the embodiment of FIG. 5 and the embodiment of FIG. 3. Unlike the first sub-pixel SPX11 having a hexagonal shape in accordance with an embodiment of FIG. 3, the first sub-pixel SPX11a of FIG. 5 may have an octagonal shape.

The first sub-pixel SPX11a may include first to eighth edges s1 to s8. The first edge s1 may extend in the first direction DR1. The second edge s2 may extend in the second direction DR2 and be connected to the first edge s1. The third edge s3 may extend parallel to the first edge s1. The fourth edge s4 may extend parallel to the second edge s2. The fourth edge s4 may be connected to the third edge s3. The fifth edge s5 may be connected to the second edge s2. The sixth edge s6 may connect the fifth edge s5 with the third edge s3. The seventh edge s7 may be connected to the first edge s1. The seventh edge s7 may be parallel to the sixth edge s6. The eighth edge s8 may connect the fourth edge s4 with the seventh edge s7. The eighth edge s8 may be parallel to the fifth edge s5.

In an embodiment, the fifth edge s5 may have a second angle ag2 with respect to an edge (e.g., a third alignment line a13) of a long side of each of the lenticular lenses. Here, the second angle ag2 may be less than the first angle ag1. The sixth edge s6 may have a third angle ag3 with respect to an edge (e.g., the third alignment line a13) of the long side of each of the lenticular lenses. The third angle ag3 may be less than the first angle ag1. In an embodiment, the second angle ag2 and the third angle ag3 may be equal to each other. For example, the second angel ag2 and the third angle ag3 each may be set to an angle greater than 0° and equal to or less than 0.5°.

Here, as illustrated in FIG. 2, the pixel component 14 and the long side LS1s1 of the lens LS1 form the first angle ag1. However, during a process of fabricating the display device, the pixel component 14 and the lens array LSA may be misaligned from each other. For example, the lens array LSA may have an orientation rotated in a clockwise direction or a counterclockwise direction based on the pixel component 14. Here, the pixel component 14 and the long side LS1s1 of the lens LS1 might not form the first angle ag1.

In the case of the present embodiment, the second angle ag2 may define an alignment error range allowed when the lens array LSA is rotated in the clockwise direction. For example, in the case where the first sub-pixel SPX11a has a shape such that the second angle ag2 is 0.5°, even if the lens array LSA is rotated by 0.5° or less in the clockwise direction, crosstalk attributable to the first sub-pixel SPX11a may be prevented from occurring. Here, there is still the probability of occurrence of crosstalk attributable to other sub-pixels (e.g., the fourth sub-pixel SPX21a). The crosstalk may be mitigated by increasing a width BMWD between the first sub-pixel SPX11a and the fourth sub-pixel SPX21a. Likewise, the third angle ag3 may define an alignment error range allowed when the lens array LSA is rotated in the counterclockwise direction.

If the lens array LSA has an orientation rotated by 0.5° or more in the clockwise direction or the counterclockwise direction, the quality of a stereoscopic image may be markedly reduced. Therefore, it is desirable that each of the second angle ag2 and the third angle ag3 be set to 0.5° or less.

In a display device according to the present disclosure, crosstalk between different viewpoints may be minimized.

In the display device according to the present disclosure, an allowable range of an alignment error between a lens array and a pixel component may be increased.

Although the preferred embodiments of the present disclosure have been disclosed for illustrative purposes, those skilled in the art will appreciate that various modifications, additions and substitutions are possible, without departing from the scope and spirit of the present disclosure.

What is claimed is:

1. A display device, comprising:
a plurality of sub-pixels arranged in a first direction and a second direction perpendicular to the first direction; and
a plurality of lenticular lenses arranged such that an edge of a long side of each of the plurality of lenticular lenses has a first angle with respect to the second direction,
wherein a first sub-pixel of the plurality of sub-pixels comprises:
a first edge extending in the first direction;
a second edge connected to the first edge, the second edge extending in the second direction;
a third edge parallel to the first edge;
a fourth edge parallel to the second edge; and
a fifth edge connecting the second edge to the third edge.

2. The display device according to claim 1, wherein the fifth edge extends parallel to the edge of the long side of each of the plurality of lenticular lenses.

3. The display device according to claim 2, wherein the first sub-pixel further comprises a sixth edge connecting the first edge to the fourth edge.

4. The display device according to claim 3, wherein the sixth edge extends parallel to the edge of the long side of each of the plurality of lenticular lenses.

5. The display device according to claim 4,
wherein the first sub-pixel corresponds to a first color,
wherein the plurality of sub-pixels further includes:
a second sub-pixel disposed on a side of the first sub-pixel in the first direction and corresponding to a second color; and
a third sub-pixel disposed on a side of the second sub-pixel in the first direction and corresponding to a third color, and
wherein the first color, the second color, and the third color differ from each other.

6. The display device according to claim 5, wherein the plurality of sub-pixels further include a fourth sub-pixel disposed on a side of the first sub-pixel in the second direction and corresponding to a first color.

7. The display device according to claim 5, wherein each of the second sub-pixel and the third sub-pixel comprises an edge aligned with the first edge of the first sub-pixel in the first direction.

8. The display device according to claim 7, wherein each of the second sub-pixel and the third sub-pixel further comprises an edge aligned with the third edge of the first sub-pixel in the first direction.

9. The display device according to claim 6, wherein the fourth sub-pixel comprises an edge aligned with the second edge of the first sub-pixel in the second direction.

10. The display device according to claim 9, wherein the fourth sub-pixel further comprises an edge aligned with the fourth edge of the first sub-pixel in the second direction.

11. A display device, comprising:
a plurality of sub-pixels arranged in a first direction and a second direction perpendicular to the first direction; and
a plurality of lenticular lenses arranged such that an edge of a long side of each of the plurality of lenticular lenses has a first angle with respect to the second direction,
wherein a first sub-pixel of the plurality of sub-pixels comprises:
a first edge extending in the first direction;
a second edge connected to the first edge, the second edge extending in the second direction;
a third edge parallel to the first edge;
a fourth edge parallel to the second edge;
a fifth edge including one end connected to the second edge; and
a sixth edge connecting the fifth edge to the third edge.

12. The display device according to claim 11,
wherein the fifth edge has a second angle with respect to the edge of the long side of each of the plurality of lenticular lenses, and
wherein the second angle is less than the first angle.

13. The display device according to claim 12,
wherein the sixth edge has a third angle with respect to the edge of the long side of each of the plurality of lenticular lenses, and
wherein the third angle is less than the first angle.

14. The display device according to claim 13, wherein the second angle is equal to the third angle.

15. The display device according to claim 11, wherein the first sub-pixel further comprises:
a seventh edge including one end connected to the first edge; and
an eighth edge connecting the fourth edge with the seventh edge.

16. The display device according to claim 15,
wherein the seventh edge is parallel to the sixth edge, and
wherein the eighth edge is parallel to the fifth edge.

17. The display device according to claim 11,
wherein the first sub-pixel corresponds to a first color,
wherein the plurality of sub-pixels further include:
a second sub-pixel disposed on a side of the first sub-pixel in the first direction and corresponding to a second color; and
a third sub-pixel disposed on a side of the second sub-pixel in the first direction and corresponding to a third color, and
wherein the first color, the second color, and the third color differ from each other.

18. The display device according to claim 17, wherein the plurality of sub-pixels further include a fourth sub-pixel disposed on a side of the first sub-pixel in the second direction and corresponding to a first color.

19. The display device according to claim 17,
wherein each of the second sub-pixel and the third sub-pixel comprises an edge aligned with the first edge of the first sub-pixel in the first direction, and
wherein each of the second sub-pixel and the third sub-pixel further comprises an edge aligned with the third edge of the first sub-pixel in the first direction.

20. The display device according to claim 18,
wherein the fourth sub-pixel comprises an edge aligned with the second edge of the first sub-pixel in the second direction, and
wherein the fourth sub-pixel further comprises an edge aligned with the fourth edge of the first sub-pixel in the second direction.
